(19) United States
(12) Patent Application Publication
(10) Pub. No.: US 2022/0325430 A1
(43) Pub. Date: Oct. 13, 2022

(54) SUBSTRATE HOLDER AND SUBSTRATE TREATMENT APPARATUS

(71) Applicant: EBARA CORPORATION, Tokyo (JP)

(72) Inventors: Masaya SEKI, Tokyo (JP); Kiyoshi SUZUKI, Tokyo (JP); Masayuki SATAKE, Tokyo (JP)

(21) Appl. No.: 17/763,858

(22) PCT Filed: Aug. 20, 2020
(86) PCT No.: PCT/JP2020/031380

§ 371 Date: Mar. 25, 2022

(30) Foreign Application Priority Data
Oct. 4, 2019 (JP) 2019-183674

(51) Int. Cl. C25D 17/08; C25D 7/12; H01L 21/687

(52) U.S. Cl. CPC C25D 17/08; C25D 7/12; H01L 21/68721

(57) ABSTRACT

Provided is a substrate holder and a substrate treatment apparatus capable of positioning a substrate even in a case in which the substrate receives a frictional force and the like from a support surface. A substrate holder 200 according to the present invention includes: a first holding member 300; a second holding member 500 adapted to pinch a substrate W with the first holding member 300; three or more positioning members 360 including contact surfaces 342 that come into contact with side end portions of the substrate W; a first moving member 380 including a plurality of engaging portions 384 that are engaged with the positioning members 360 such that the positioning members 360 with a state in which distances of an ideal axis L and contact surfaces 376 of the positioning members 360 are equal to each other maintained; and a first biasing member 310 adapted to bias the first moving member 380, in which the first moving member 380 delivers a biasing force of the first biasing member 310 to each of the positioning members 360, and the positioning members 360 are biased in a direction in which the contact surfaces 376 approaches the ideal axis L with the delivered biasing force.

### TECHNICAL FIELD

The present invention relates to a substrate holder and a substrate treatment apparatus.

### BACKGROUND ART

In order to form thin metal films on surfaces of substrates, plating apparatuses are used. In the plating apparatuses, substrate holders that detachably hold substrates such as semiconductor wafers may be used. Also, the plating apparatuses are adapted to plate the surfaces of the substrates by immersing the substrates held by the substrate holders in plating solutions and applying voltages to the substrates.

One example of the substrate holders is described in PTL 1. PTL 1 discloses a substrate holder including: a first holding member that includes a first surface configured to come into contact with a substrate; and a second holding member that holds the substrate by pinching the substrate with the first holding member as illustrated in FIG. 3 thereof. Also, the first holding member of the substrate holder includes a positioning member that positions the substrate in contact with the first surface at a predetermined position on the first surface. In addition, the positioning member is configured to move between a first position at which the positioning member comes into contact with a peripheral edge portion of the substrate and positions the substrate at the predetermined position on the first surface and a second position at which the positioning member is located on a side further outward than the peripheral edge portion of the substrate and does not come into contact with the substrate. The second holding member includes a drive member configured to locate the positioning member at the first position when the substrate is held by the first holding member and the second holding member.

Also, the positioning member includes a distal end portion in the substrate holder as illustrated in FIG. 7 thereof. The distal end portion is split into a first distal end portion and a second distal end portion, and a space is generated between the first distal end portion and the second distal end portion. The first distal end portion is located inward in a radial direction of the substrate, and the second distal end portion is located outward in the radial direction of the substrate. Also, the first distal end portion is configured to come into contact with the substrate, and the second distal end portion is configured to come into contact with the drive member.

According to the substrate holder described in PTL 1, the drive member comes into contact with the second distal end portion and can move the position member to the first position when the substrate is held by the first holding member and the second holding member. At this time, the substrate holder can position the substrate by the first distal end portion of the positioning member that has moved to the first position coming into contact with the substrate. Here, the space is present between the first distal end portion and the second end portion as described above. Therefore, the first distal end portion can come into contact with the substrate with slight elasticity, and even in a case of a substrate with a size difference of several mm, the positioning member can position the substrate with a different size with the first distal end portion absorbing the dimension difference of several mm.

Also, another example of the substrate holders is described in PTL 2. PTL 2 discloses a substrate holder including: a movable holding member, and a fixed holding member as illustrated in FIG. 10 thereof. The substrate holder is characterized by being provided, at the movable holding member, with a plurality of leaf spring members with a spring property that elastically come into contact with an outer peripheral end portion of a substrate and position the substrate when the substrate is held by the movable holding member and the fixed holding member.

According to the substrate holder described in PTL 2, it is possible to position (center) the substrate relative to the substrate holder via the leaf spring members by biasing the substrate inward with an elastic force of the leaf spring members with the spring property in a process of holding the substrate.

### CITATION LIST

### Patent Literature

PTL 1: Japanese Patent Laid-Open No. 2018-9215
PTL 2: Japanese Patent Laid-Open No. 2004-76022

### SUMMARY OF INVENTION

### Technical Problem

Yet higher levels of positioning accuracy for substrates have been required with evolution of devices. On the other hand, PTL 2 describes that the plurality of leaf spring members (positioning members) with elasticity are disposed to position a substrate as described above. However, since the leaf spring members that individually have elasticity mutually push the substrate in presence of a frictional force and the like between the substrate and a support surface, in practice, the amount of deformation of the leaf spring members may not necessarily the same as a result, and in other words, there is a problem that holding of the substrate is completed with insufficient positioning accuracy for the substrate.

Also, the substrate holder described in PTL 1 has a problem that is basically similar to that of the substrate holder described in PTL 2 since the space between the first distal end portion and the second distal end portion have an effect similar to that of the leaf spring members described in PTL 2.

Thus, in view of the aforementioned problem, an object of the present invention is to provide a substrate holder and a substrate treatment apparatus capable of positioning a substrate even in a case in which the substrate receives a frictional force and the like from a support surface.

### Solution to Problem

A substrate holder according to the present invention is a substrate holder that includes a support surface for supporting a substrate and positions the substrate such that a center axis of the substrate is located on an ideal axis extending in a direction perpendicularly intersecting the support surface, the substrate holder including: a first holding member; a second holding member adapted to pinch the substrate with the first holding member; three or more positioning members including contact surfaces that come into contact with side end portions of the substrate; a first moving member including a plurality of engaging portions that are engaged with the positioning members such that the positioning members are moved at the same time with a state in which distances between the ideal axis and the contact surfaces of the positioning members are equal to each other maintained; and a first biasing member adapted to bias the first moving member, in which the first moving member delivers a biasing force of the first biasing member to each of the positioning members via the engaging portions, and each of the positioning members is biased in a direction in which the contact surfaces approach the ideal axis with the biasing force delivered from the first biasing member.

In the substrate holder according to the present invention, each of the positioning members is biased in a direction in which the contact surfaces approach the ideal axis. Therefore, in a case in which the substrate is placed on the support surface, the contact surfaces of the positioning members come into contact with the side end portions of the substrate and push the substrate in the direction of the ideal axis. In this manner, the three or more positioning members position the substrate by pinching the substrate from the surroundings thereof. At this time, the first moving member maintains the state in which the distances between the ideal axis and the contact surfaces of the positioning members are equal to each other. Therefore, if the substrate has a circular shape, then the three or more positioning members can position the center of the pinched substrate on the ideal axis. As a result, the center of the substrate after the positioning is located on the ideal axis even in a case in which the substrate receives a frictional force and the like from the support surface. In other words, the substrate holder can position the substrate even in a case in which the substrate receives a frictional force and the like from the support surface.

### BRIEF DESCRIPTION OF DRAWINGS

FIG. 1 is an overall disposition diagram of a plating apparatus that performs a plating treatment using a substrate holder according to a first embodiment.

FIG. 2 is a perspective view of the substrate holder according to the first embodiment.

FIG. 3 is a schematic diagram of the substrate holder illustrated in FIG. 2 when seen from a front direction.

FIG. 4 is a partial enlarged view of the substrate holder illustrated in FIG. 2 in a state in which a substrate is held along a cut plane in a thickness direction.

FIG. 5 is a front view of a portion of a first member of the substrate holder illustrated in FIG. 2.

FIG. 6 is a sectional view along A-A in FIG. 5 and is a diagram illustrating a positioning member located at a first position.

FIG. 7 is a sectional view along A-A in FIG. 5 and is a diagram illustrating the positioning member located at a second position.

FIG. 8 is a sectional perspective view of the positioning member.

FIG. 9 is a partial sectional view of a substrate holder 200 when seen from a back direction.

FIG. 10 is an enlarged view of the portion B in FIG. 9.

FIG. 11 is an enlarged view of the portion C in FIG. 9 and is a diagram illustrating a second moving member located at a steady-state position.

FIG. 12 is an enlarged view of the portion C in FIG. 9 and is a diagram illustrating the second moving member located at a displaced position.

FIG. 13 is an enlarged view of the portion C in FIG. 9 and is a diagram illustrating the second moving member located at the displaced position.

FIG. 14(a) is a schematic view of the section along D-D in FIG. 3, and FIG. 14(b) is a sectional view along E-E in FIG. 14(a).

FIG. 15(a) is a schematic view of the section along D-D in FIG. 3 in a state in which a second member is being closed, and FIG. 15(b) is a sectional view along F-F in (a).

FIG. 16 is a schematic view illustrating a modification example of the substrate holder illustrated in FIG. 2.

FIG. 17 is a schematic view illustrating another modification example of the substrate holder illustrated in FIG. 2.

FIG. 18 is a schematic view illustrating another modification example of the substrate holder illustrated in FIG. 2.

FIG. 19 is a schematic view illustrating another modification example of the substrate holder illustrated in FIG. 2.

### DESCRIPTION OF EMBODIMENTS

### First Embodiment

Hereinafter, the present embodiment will be described with reference to the drawings. First, an overall configuration of a plating apparatus 100 including a substrate holder 200 according to the present embodiment will be described. Next, a configuration of the substrate holder 200 according to the present embodiment will be described. Then, a method for pinching a positioned substrate W in the substrate holder 200 will be described. Then, effects of the substrate holder 200 will be described. Then, modification examples of the substrate holder 200 will be described. Note that the same reference signs will be applied to the same or corresponding components in the drawings described below and repeated description will be omitted.

<Overall Configuration of Plating Apparatus>

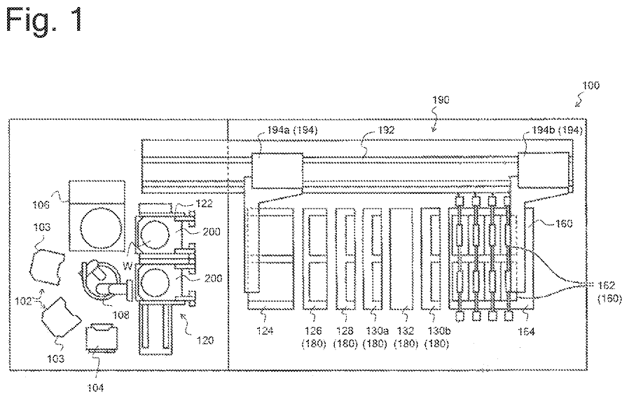

FIG. 1 is an overall disposition diagram of a plating apparatus 100 that performs a plating treatment using a substrate holder 200 according to a first embodiment. Referring to FIG. 1, the plating apparatus 100 includes two cassette tables 102, an aligner 104, a spin rinse dryer 106, a substrate transfer device 108, and a substrate attachment/detachment 120. Although the plating apparatus 100 is a wet-type vertical electroplating apparatus in one example, the plating apparatus 100 may be of a horizontal type and may be an electroplating apparatus or an electroless plating apparatus of a dry type. Also, the plating apparatus 100 performs plating on the substrate W with a circular shape in one example.

First, each component of the plating apparatus 100 will be described. The cassette tables 102 have a function of being loaded with a cassette 103 accommodating the substrate W such as a semiconductor wafer therein. The spin rinse dryer 106 has a function of rotating the substrate W after the plating treatment at a high speed to dry the substrate W. The substrate attachment/detachment 120 includes two placement plates 122. The substrate attachment/detachment 120 performs attachment and detachment of the substrate W to and from the substrate holder 200 placed on the placement plates 122.

The substrate transfer device 108 is disposed in the middle of the cassette table 102, the aligner 104, the spin rinse dryer 106, and the substrate attachment/detachment 120. The substrate transfer device 108 has a function of transferring the substrate W among the cassette table 102, the aligner 104, the spin rinse dryer 106, and the substrate attachment/detachment 120. The substrate transfer device 108 is constituted by a transfer robot in one example.

The plating apparatus 100 further includes a stocker 124, a pre-wet tank 126, a pre-soak tank 128, a first washing tank 130a, a blow tank 132, a second washing tank 130b, and a plating unit 160. The stocker 124 performs storage and temporary placement of the substrate holder 200. The pre-wet tank 126 holds pure water. The pre-wet tank 126 enhances hydrophilicity of the substrate W by immersing the substrate W in pure water and wetting the surface. The pre-soak tank 128 holds a sulfuric acid. The pre-soak tank 128 has a function of etching-removing an oxide film on the surface of a conductive layer such as a seed layer or the like formed on the surface of the substrate W with the sulfuric acid. The first washing tank 130a holds a washing solution (such as pure water). The first washing tank 130a can wash the substrate W after the pre-soaking along with the substrate holder 200 with the washing solution (such as pure water). The blow tank 132 has a function of performing liquid removing from the substrate W after the washing. The second washing tank 130b has a function of washing the substrate W after the plating along with the substrate holder 200 with the washing solution.

The plating unit 160 includes a plurality of adjacent plating tanks 162 and an overflow tank 164 that surrounds the outer periphery of the plurality of plating tanks 162 in one example. Each plating tank 162 accommodates one substrate W therein and is configured to immerse the substrate W into a plating solution held therein and performs plating, such as copper plating, on the surface of the substrate W in one example. Note that the pre-wet tank 126, the pre-soak tank 128, the first washing tank 130a, the blow tank 132, the second washing tank 130b, and the plating tank 162 can be referred to as treatment tanks 180. In other words, the treatment tanks 180 are tanks for treating the substrate W.

The plating apparatus 100 further includes a substrate holder transfer device 190. Also, the substrate holder transfer device 190 includes a horizontal rail 192, a first transporter 194a, and a second transporter 194b. Note that the first transporter 194a and the second transporter 194b have the same structure and each of the first transporter 194a and the second transporter 194b can be simply referred to as a transporter 194. The substrate holder transfer device 190 is located on a side of the substrate attachment/detachment 120, the stocker 124, the pre-wet tank 126, the pre-soak tank 128, the first washing tank 130a, the blow tank 132, the second washing tank 130b, and the plating unit 160 that are linearly aligned. A linear motor scheme is employed for the substrate holder transfer device 190 in one example. The horizontal rail 192 linear extends to be adjacent to each of the treatment tanks 180 that are linearly aligned.

The first transporter 194a is configured to transfer the substrate holder 200 among the substrate attachment/detachment 120, the stocker 124, the pre-wet tank 126, the pre-soak tank 128, the first washing tank 130a, and the blow tank 132 in one example. The second transporter 194b is configured to transfer the substrate holder 200 among the first washing tank 130a, the second washing tank 130b, the blow tank 132, and the plating tank 162 in one example.

<Configuration of Substrate Holder>

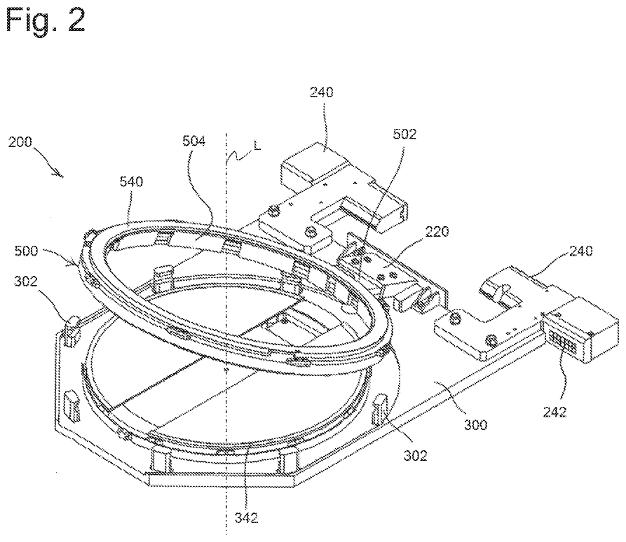

Next, the substrate holder 200 used in the plating apparatus 100 illustrated in FIG. 1 will be described in detail. FIG. 2 is a perspective view of the substrate holder 200. Referring to FIG. 2, the substrate holder 200 includes a first member 300 (an example of the first holding member), a second member 500 (an example of the second holding member), a hinge 220, and a pair of hands 240. The second member 500 includes a seal holder 540 with an annular shape and a base portion 502 with a flat plate shape extending from the seal holder 540 to the hinge 220 and supported by the hinge 220. Also, the hinge 220 connects the second member 500 to the first member 300. Therefore, the second member 500 is configured to be rotatable using the hinge 220 as a support point. Also, the substrate holder 200 can pinch the substrate W with the first member 300 and the second member 500 by the second member 500 rotating and closing. In other words, the substrate holder 200 has a function of holding the substrate W. An opening 504 is formed in the second member 500. The opening 504 is slightly smaller than the size of the substrate W. When the substrate W is pinched between the first member 300 and the second member 500, a surface to be treated of the substrate W is exposed through the opening 504. In other words, a treatment solution in the treatment tank 180 can come into contact with the exposed surface to be treated of the substrate W when the substrate holder 200 is held at the treatment tank 180. In this manner, a treatment is performed on the surface to be treated of the substrate W.

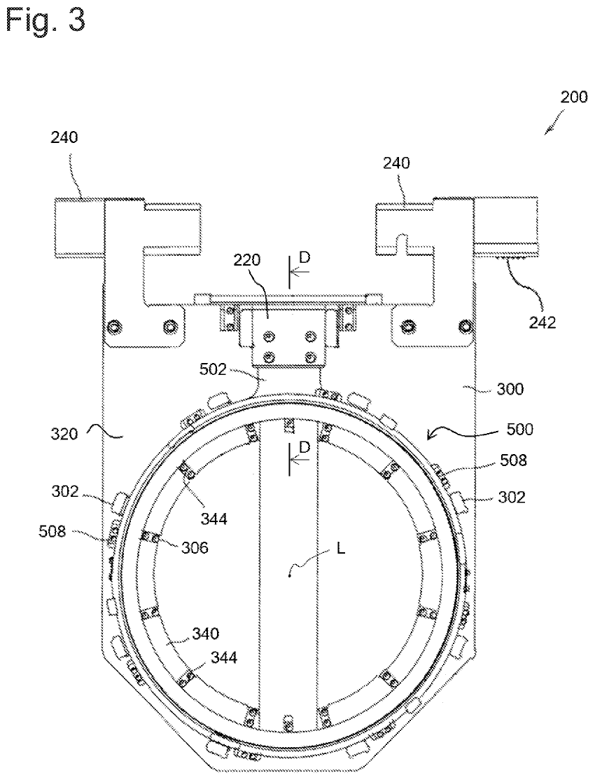

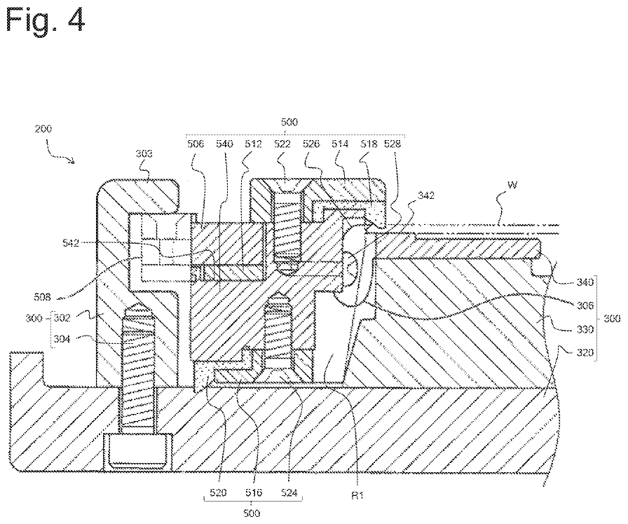

The pair of hands 240 are fixed to an end portion of the first member 300. Each hand 240 has a T shape and serves as a support when the substrate holder 200 is transferred or supported in a suspended manner in one example. The substrate holder 200 is supported in a vertically suspended state by the hands 240 being hooked at a peripheral wall upper surface of each treatment tank 180 illustrated in FIG. 1. In addition, the transporter 194 can grip the hands 240 and transfers the substrate holder 200 in a state in which the hands 240 are gripped. Also, one of the hands 240 is provided with an external contact 242 that is electrically connected to an external power source. The external contacts 242 are electrically connected to a plurality of conductive members 306 (see FIGS. 3 and 4) provided at the outer periphery of the base 340 via a plurality of conductive wires.

FIG. 3 is a schematic view of the substrate holder 200 when seen from the front direction, and FIG. 4 is a partial enlarged view of the substrate holder 200 in a state in which the substrate W is held along a cut plane in the thickness direction of the substrate holder 200. Referring to FIG. 4, the first member 300 further includes a plurality of clampers 302, a fastening tool 304, a first support base 320, a second support base 330, a base 340, and the conductive members 306. Also, the second member 500 further includes a pressure ring 506, a spacer 512, a first fixing ring 514, a second fixing ring 516, a substrate sealing member 518, a holder sealing member 520, a fastening tool 522, a fastening tool 524, contact members 526, and a fastening tool 528.

The first support base 320 has substantially a rectangular flat shape and is constituted by vinyl chloride in one example (see FIG. 3). The second support base 330 and the plurality of clampers 302 are fixed to the first support base 320. The second support base 330 has substantially a disk shape. The base 340 is fixed to the second support base 330. The base 340 has a function of supporting the substrate W. The base 340 has a support surface 342 that has a ring shape around a center axis L and abuts an outer peripheral portion of the substrate W to support the substrate W. Note that the center axis L and the support surface 342 perpendicularly intersect each other (see FIG. 2). In other words, the center axis L extends in a direction that is perpendicular to the support surface 342.

The seal holder 540 is constituted by vinyl chloride in one example. Also, the first fixing ring 514 with an annular shape is attached to the seal holder 540 with the fastening tool 522. In addition, the substrate sealing member 518 with an annular shape is pinched with the seal holder 540 and the first fixing ring 514. Additionally, the second fixing ring 516 with an annular shape is attached to the seal holder 540 with the fastening tool 524. Also, the holder sealing member 520 with an annular shape is pinched with the seal holder 540 and the second fixing ring 516. In other words, the substrate sealing member 518 and the holder sealing member 520 are attached to the seal holder 540. Note that the centers of the seal holder 540, the substrate sealing member 518, and the holder sealing member 520 in one example are located on the center axis L in one example in the substrate holder 200.

The substrate sealing member 518 comes into contact with a portion near the outer periphery portion of the surface of the substrate W when the substrate holder 200 holds the substrate W. The substrate sealing member 518 has a function of sealing a clearance between the substrate W and the second member 500 in this manner. On the other hand, the holder sealing member 520 comes into contact with the first member 300 when the substrate holder 200 holds the substrate W. The holder sealing member 520 has a function of sealing a clearance between the first member 300 and the second member 500 in this manner. Therefore, if the substrate holder 200 holds the substrate W, then an inner space R1 sealed by each of the substrate sealing member 518 and the holder sealing member 520 is formed inside the substrate holder 200 as illustrated in FIG. 4.

The plurality of clampers 302 have a function of being engaged with protrusions 508, which will be described later, and fixing the second member 500 to the first member 300 along with the protrusions 508. The clampers 302 have inverted L shapes and have projecting portions 303 projecting in the direction of the support surface 342. Also, the clampers 302 are disposed at substantially equal intervals along the surroundings of the support surface 342 (see FIG. 3), and each clamper 302 is fixed to the first support base 320 with the fastening tool 304.

Also, a step portion 542 is formed at the outer peripheral portion of the seal holder 540. The pressure ring 506 is rotatably attached to the step portion 542 via the spacer 512. The pressure ring 506 is constituted by a metal (titanium, for example) with excellent corrosion resistance against acids and with sufficient rigidity in one example. The spacer 512 is constituted by a material with a low friction coefficient such that the pressure ring 506 can smoothly rotate. Note that the spacer 512 is constituted by a polytetrafluoroethylene (PTFE) in the substrate holder 200 in one example.

Also, the pressure ring 506 has the protrusions 508. The protrusions 508 are provided to project outward from the pressure ring 506 at positions facing the plurality of clampers 302 (see FIG. 3). Additionally, upper surfaces of the protrusions 508 are tapered surfaces inclined along the rotation direction of the pressure ring 506, and lower surfaces of the projecting portions 303 of the clampers 302 that come into contact with the upper surfaces of the protrusions 508 are also inclined tapered surfaces. Moreover, the protrusions 508 and the clampers 302 are configured such that the protrusions 508 slides into the projecting portions 303 of the clampers 302 by the pressure ring 506 rotating in a clockwise direction. In other words, the second member 500 is fixed to the first member 300 by the pressure ring 506 rotating in the clockwise direction. On the other hand, the fixing of the second member 500 to the first member 300 is released by the pressure ring 506 rotating in the counterclockwise direction.

Also, recessed portions 344 are formed at predetermined positions along the circumferential direction of the base 340 as illustrated in FIG. 3. The plurality of (twelve in the illustration) conductive members 306 are disposed in each recessed portion 344. Also, end portions of the conductive members 306 are configured to come into contact with the contact members 526 when the second member 500 is closed as illustrated in FIG. 4. On the other hand, the contact members 526 are configured to be separated from the conductive members 306 when the second member 500 is opened.

Also, the contact members 526 are located in the inner space R1 and are constituted by conductive leaf springs in one example. The contact members 526 are secured to the seal holder 540 with the fastening tool 528. Also, the contact members 526 are configured to come into elastic contact with the vicinity of the edges of the substrate W on the surface to be treated when the first member 300 and the second substrate 500 pinch the substrate W. In other words, when the substrate holder 200 pinches the substrate W, electric continuity is established between the external contacts 242 of the hands 240 and the substrate W. Note that the numbers of contact members 526 provided is the same as the number (twelve in the substrate holder 200) of the conductive members 306.

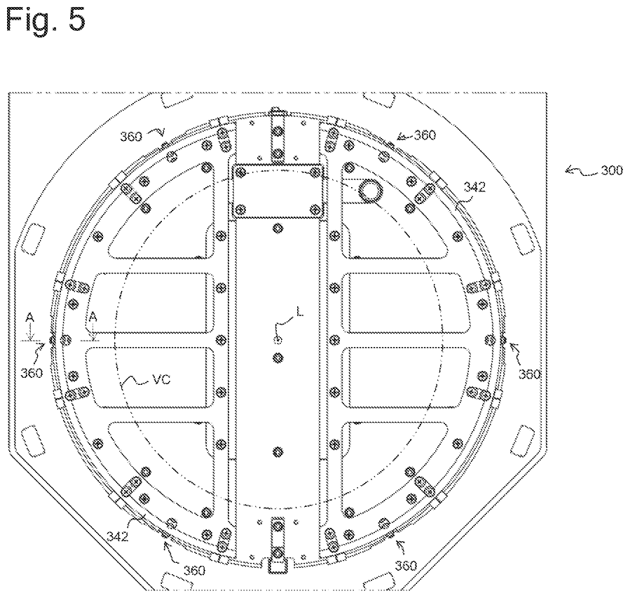

FIG. 5 is a front view of a part of the first member 300 in the substrate holder 200. Referring to FIG. 5, the first member 300 further includes six positioning members 360 disposed to surround the support surface 342. The substrate holder 200 has a function of positioning the substrate W relative to the substrate holder 200 using the positioning members 360 by a method, which will be described later. Note that in the specification, positioning means moving of the substrate W to the position at which the center of the substrate W is located on an ideal axis. Also, the ideal axis is a straight line that passes through a position at which the center of the substrate W is to be located and is perpendicular to the support surface 342 in the substrate holder 200. Moreover, the ideal axis conforms to the center axis L in the present embodiment. Therefore, in a case in which the ideal axis indicates the straight line L in the drawing, the ideal axis is described as an ideal axis L.

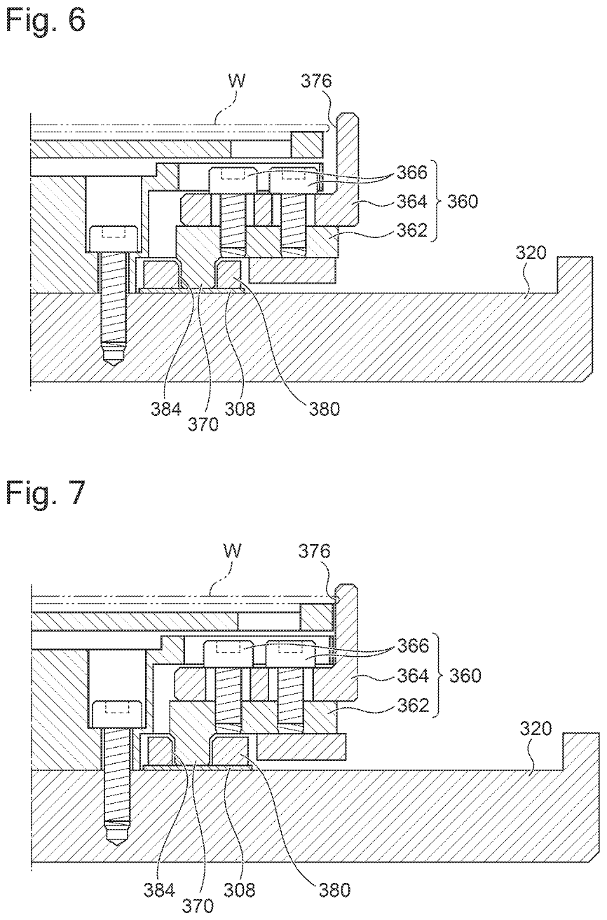

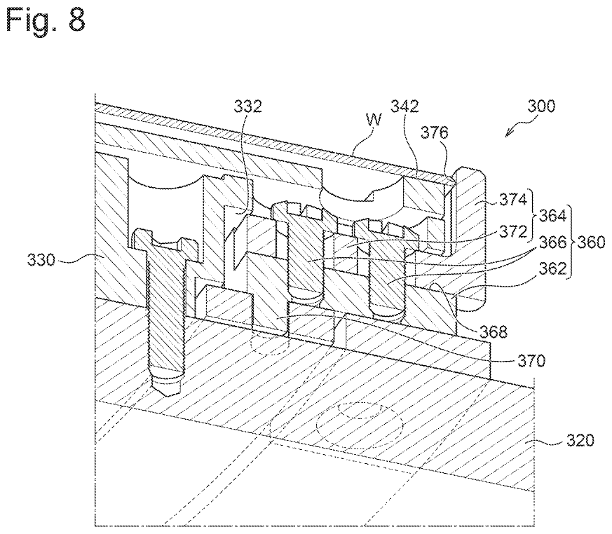

FIG. 6 is a sectional view along A-A in FIG. 5 and is a diagram illustrating the positioning member 360 located at a first position. FIG. 7 is a sectional view along A-A in FIG. 5 and is a diagram illustrating the positioning member 360 located at a second position. Also, FIG. 8 is a sectional perspective view of the positioning member 360. Note that a seat 308 is omitted for easiness of viewing in FIG. 8.

Referring to FIG. 8, the positioning member 360 is a member with substantially an L shape and includes a support member 362, an L-shaped member 364, and two fastening tools 366 in one example. The support member 362 is a rectangular parallelepiped block-shaped member, and a groove 368 linearly extending in the longitudinal direction is formed therein. Also, the support member 362 includes pins 370 (an example of the engaged portions 370) extending in parallel with the ideal axis L in a surface on the side opposite to the surface in which the groove 368 is formed. The L-shaped member 364 is a member with substantially an L shape and includes a fixed portion 372 and a distal end portion 374 that substantially perpendicularly intersects the fixed portion 372 and extends up to a portion above the support surface 342. The L-shaped member 364 is fixed to the support member 362 with two fastening tools 366 in a state in which the fixed portion 372 is fitted into the groove 368 in the support member 362. Also, the distal end portion 374 comes into contact with the substrate W at the time of the positioning of the substrate W. The surface that comes into contact with the substrate W will be referred to as a contact surface 376. In other words, the positioning member 360 includes the contact surface 376 for establishing contact with a side end portion of the substrate W.

Moreover, a groove 332 with a linear shape extending in a radial direction of a virtual circle VC (see FIG. 5) around the ideal axis L is formed in the second support base 330. The positioning member 360 is fitted into the groove 332. The positioning member 360 can thus move along the groove 332. More specifically, the positioning member 360 can move from the first position away from the ideal axis L as illustrated in FIG. 6 to the second position at which the positioning member 360 is closer to the ideal axis L than at the first position as illustrated in FIG. 7. Note that the distance between the ideal axis L and the contact surface 376 when the positioning member 360 is at the first position is longer than the radius of the substrate W while the distance between the ideal axis L and the contact surface 376 when the positioning member 360 is at the second position is shorter than the radius of the substrate W.

Also, the first member 300 further includes the seat 308 located between a first moving member 380, which will be described later, and the first support base 320 (see FIG. 6). The seat 308 is constituted by Teflon (registered trademark) in one example. In this manner, friction between the first moving member 380 and the first support base 320 when the first moving member 380 rotates is reduced.

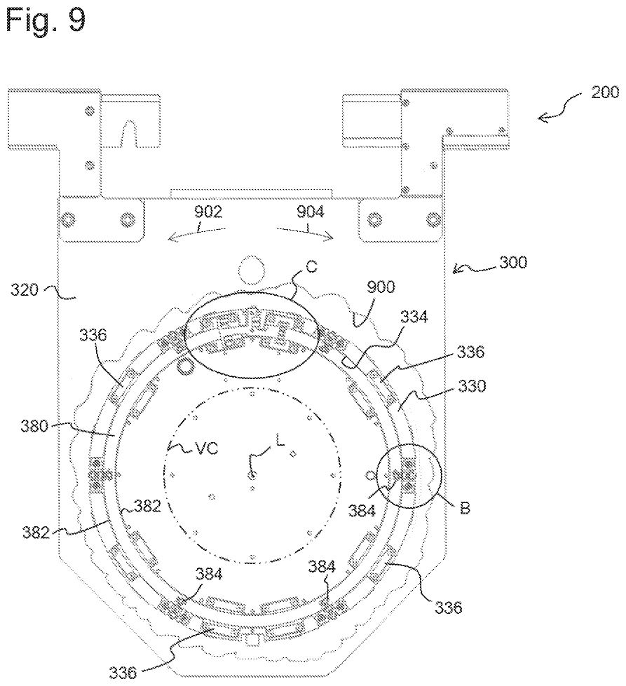

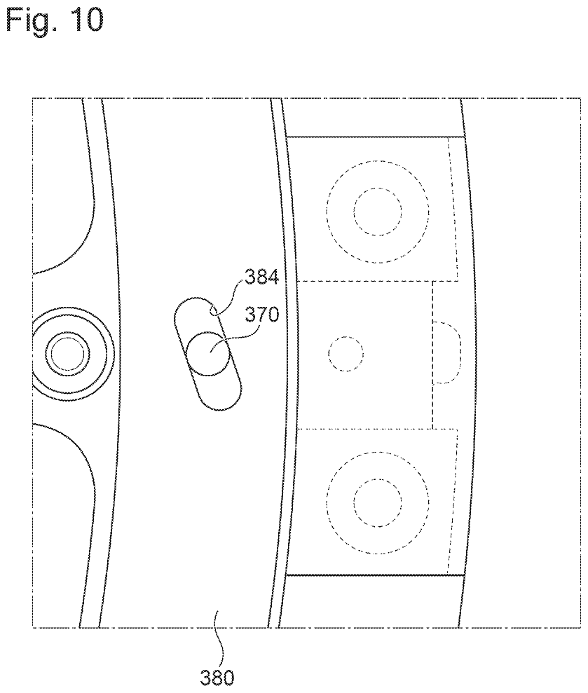

FIG. 9 is a partial sectional view of the substrate holder 200 when seen from the back direction. The first support base 320 is omitted inside the sectional line 900 in FIG. 9. FIG. 10 is an enlarged view of the portion B in FIG. 9. The direction indicated by the arrow 902 in FIG. 9 is defined as a first rotation direction 902, and the rotation direction opposite to the first rotation direction 902 is defined as a second rotation direction 904.

Referring to FIG. 9, the first member 300 further includes the first moving member 380. The first moving member 380 is a member with an arc shape in one example. Also, the first moving member 380 includes a pair of side surfaces 382 extending in the circumferential direction of the virtual circle VC around the ideal axis L. In addition, a groove 334 with an arc shape around the ideal axis L is formed in the second support base 330. Moreover, the second support base 330 includes a plurality of guide members 336. The guide members 336 have a function of coming into contact with each of the side surfaces 382 of the first moving member 380 to guide the first moving member 380 in the circumferential direction of the virtual circle VC around the ideal axis L. Therefore, the first moving member 380 is guided by the plurality of guide members 336 in a state in which the first moving member 380 is fitted into the groove 334. In other words, the first moving member 380 is configured to be rotatable about the ideal axis L.

Also, a plurality of long holes 384 (an example of the engaging portions 384) corresponding to the positioning members 360 are formed in the first moving member 380 as illustrated in FIG. 9. Also, the longitudinal direction of the long holes 384 are directions that intersect the radial direction and the circumferential direction of the virtual circle VC around the ideal axis L. The long holes 384 are engaged with pins 370 of the positioning members 360 (see FIG. 10). In this manner, if the first moving member 380 rotates, then the positioning members 360 move in conjunction with the first moving member 380. Specifically, if the first moving member 380 rotates in the second rotation direction 904 when the positioning members 360 are at the first position as illustrated in FIG. 6, then the long holes 384 move, and the pins 370 engaged with the long holes 384 are pulled in the direction of the ideal axis L by side peripheral surfaces of the long holes 384. Also, the positioning members 360 move in the direction of the ideal axis L with a tensile force from the side peripheral surfaces of the long holes 384 and then reaches the second position illustrated in FIG. 7. On the other hand, in a case in which the first moving member 380 rotates in the first rotation direction 902 when the first moving member 380 is at the second position illustrated in FIG. 7, the positioning members 360 are pulled in the direction away from the ideal axis L and moves to the first position illustrated in FIG. 6. Note that since the positioning members 360 and the first moving member 380 are connected as described above in the substrate holder 200, no biasing members such as leaf springs or elastic springs for biasing the positioning members 360 are present between the positioning members 360 and the first moving member 380.

Also, the plurality of long holes 384 move at once when the first moving member 380 rotates. In this manner, the first moving member 380 can cause each of the plurality of positioning members 360 to operate at the same time. In other words, if the first moving member 380 rotates, then the rotation of the first moving member 380 is delivered to the positioning members 360 via the long holes 384 and the pins 370, and the positioning members 360 move in the radial direction of the virtual circle VC around the ideal axis L. Also, the positioning members 360 and the first moving member 380 are configured to maintain a state in which the distances between the ideal axis L and the contact surfaces 376 of the positioning members 360 are equal to each other when the positioning members 360 move.

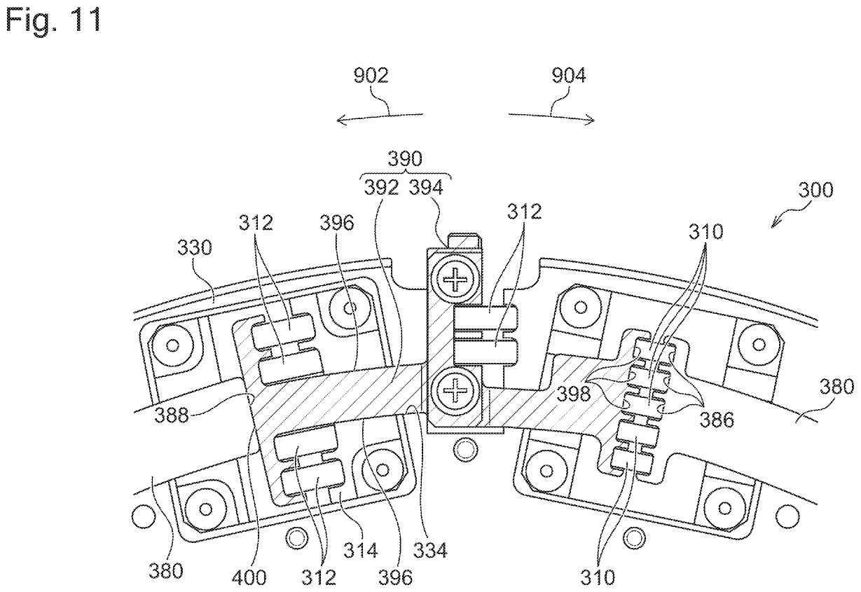

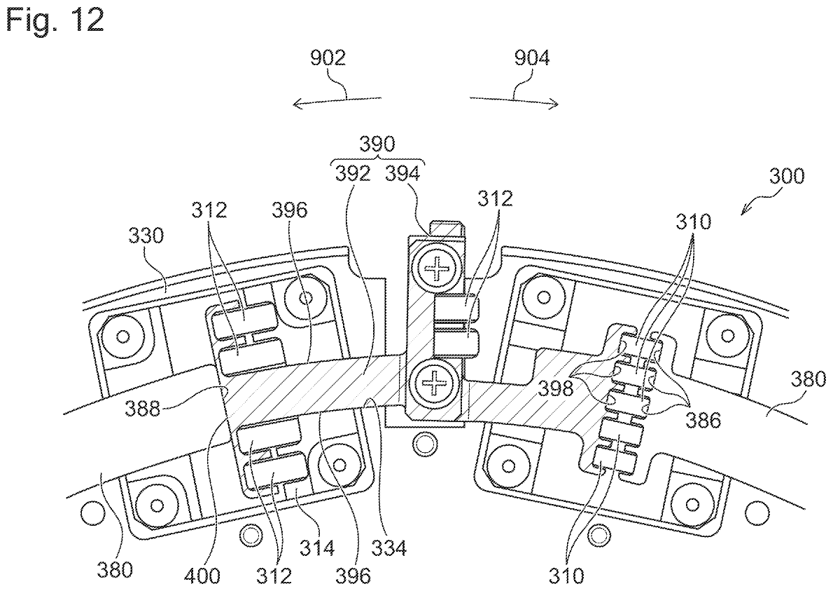

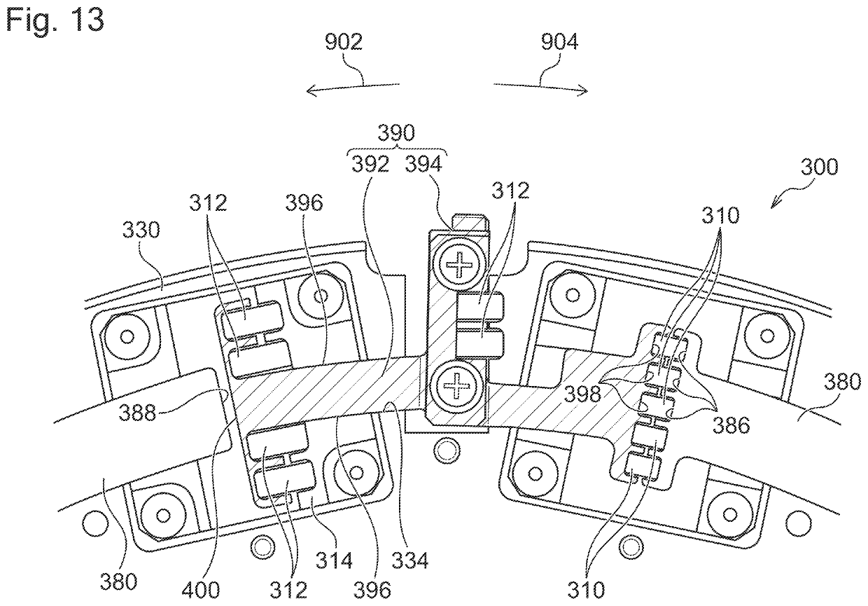

FIG. 11 is an enlarged view of the portion C in FIG. 9 and is a diagram illustrating the second moving member 390 located at a steady-state position, and in FIG. 11, a second pressurized surface 388 abuts a second pressurizing surface 400. Also, FIG. 12 is an enlarged view of the portion C in FIG. 9 and is a diagram illustrating the second moving member 390 located at a displaced position and the second pressurized surface 388 abutting the second pressurizing surface 400. FIG. 13 is an enlarged view of the portion C in FIG. 9 and is a diagram illustrating the second moving member 390 located at the displaced position and the second pressurized surface 388 separated from the second pressurizing surface 400.

Referring to FIG. 11, the first member 300 includes the second moving member 390 and a guide member 314. The second moving member 390 is a part indicated by hatching in FIG. 11. The second moving member 390 is fitted into the groove 334 in the second support base 330. Also, the second moving member 390 includes a rotation member 392 with an arc shape and an abutted member 394 extending in the radial direction of the virtual circle VC around the ideal axis L from the rotation member 392. The rotation member 392 includes a pair of side surfaces 396 extending in the circumferential direction of the virtual circle VC around the ideal axis L. Also, the guide member 314 is located inside the groove 334 in the second support base 330. Additionally, the guide member 314 has a function of coming into contact with each of the side surfaces 396 of the rotation member 392 and guiding the rotation member 392 in the circumferential direction of the virtual circle VC around the ideal axis L. The second moving member 390 is configured to be rotatable about the ideal axis L in this manner. Also, rotation is restricted by the second moving member 390 abutting the second support base 330. The second moving member 390 can thus rotate from the steady-state position illustrated in FIG. 11 to the displaced position illustrated in FIGS. 12 and 13. Note that the displaced position is a position where the second moving member 390 has moved in the second rotation direction 904 from the steady-state position and has then stopped in one example.

Also, the first member 300 includes a plurality of first biasing members 310. The first biasing members 310 are members with elasticity and are springs in one example. Additionally, the second moving member 390 includes a plurality of first pressurizing surfaces 398 in one example. The first moving member 380 includes first pressurized surfaces 386 facing the first pressurizing surfaces 398 in one example. The first biasing members 310 are located between the first pressurized surfaces 386 and the first pressurizing surfaces 398 and bias the first moving member 380 in the second rotation direction 904 via the first pressurized surfaces 386. In other words, the first biasing members 310 are in a compressed state. When the first moving member 380 rotates in the second rotation direction 904 with a biasing force from the first biasing members 310, the biasing force of the first biasing members 310 is delivered to the positioning members 360 via the long holes 384 and the pins 370. As a result, the contact surfaces 376 are biased in the direction toward the ideal axis L with the biasing force delivered from the first biasing members 310 (see FIG. 9). Then, the positioning members 360 move in the radial direction of the virtual circle VC around the ideal axis L. In other words, the first moving member 380 has a function of delivering the biasing force of the first biasing member 310 to each of the positioning members 360.

Also, the second moving member 390 includes the second pressurizing surface 400 in one example, and the first moving member 380 includes the second pressurized surface 388 facing the second pressurizing surface 400 in one example. In addition, the first moving member 380 is biased in the direction in which the second pressurized surface 388 approaches the second pressurizing surface 400, and the second pressurized surface 388 abuts the second pressurizing surface 400 by the first biasing member 310 biasing the first moving member 380 (see FIG. 9).

Here, a behavior of each component in a case in which the second moving member 390 rotates in the second rotation direction 904 from the steady-state position illustrated in FIG. 11 will be described. In a case in which the second moving member 390 receives an external force and rotates in the second rotation direction 904 from the steady-state position when there is no substrate W on the base 340, the second pressurized surface 388 rotates along with the second pressurizing surface 400 without being separated therefrom as illustrated in FIG. 12. In other words, when the second moving member 390 rotates about the ideal axis L, the first moving member 380 rotates in the same rotation direction as that of the second moving member 390. At this time, the aforementioned positioning members 360 move in the direction toward the ideal axis L in conjunction with rotation of the first moving member 380.

On the other hand, in a case in which the second moving member 390 receives an external force and rotates in the second rotation direction 904 from the steady-state position when the substrate W is placed on the base 340, the second pressurized surface 388 initially rotates along with the second pressurizing surface 400 similarly to the case where no substrate W is placed on the base 340. At this time, the positioning members 360 move in the direction toward the ideal axis L in conjunction with the rotation of the first moving member 380. However, if each positioning member 360 has pinched the side end portion of the substrate W, and the positioning members 360 have completed the positioning of the substrate W, it becomes not possible for the positioning members 360 to move due to a reactive force from the substrate W. Then, it becomes not possible for the first moving member 380 to rotate. Furthermore, if the second moving member 390 rotates in the second rotation direction 904, the first biasing member 310 is compressed without the first moving member 380 being rotated. Therefore, the second pressurizing surface 400 is separated from the second pressurized surface 388 as illustrated in FIG. 13. In other words, the second moving member 390 can rotate in a state in which the positioning members 360 stop by the first biasing member 310 playing a role of a cushion in the substrate holder 200. In this manner, the second moving member 390 can rotate in the second rotation direction 904 even after the positioning members 360 completes the positioning of the substrate W. This is for reliably completing the positioning of the substrate W before the second member 500 is completely closed and for reliably positioning the substrate W even if there are variations in size of the substrate W.

Although FIG. 12 has been used to explain the behavior of each component in the case in which no substrate W is placed as described above, a state after the positioning members 360 have completed the positioning of the substrate W in the process of closing of the second member 500 with the presence of the substrate W is also substantially the same as the state illustrated in FIG. 12. In other words, the second pressurized surface 388 and the second pressurizing surface 400 are in contact with each other as in the state illustrated in FIG. 12 at the timing when the positioning of the substrate W is completed in a description of an ideal behavior. Note that at this time, the first moving member 380 and the second moving member 390 may be located at positions after rotation in the first rotation direction 902 unlike the state illustrated in FIG. 12 depending on the positions of the positioning members 360. This will be understood by those skilled in the art from the above description.

Next, a behavior of each component in a case in which the second moving member 390 rotates in the first rotation direction 902 from the displaced position illustrated in FIG. 12 will be described. In a case in which the second moving member 390 rotates in the first rotation direction 902 when the second moving member 390 is located at the position illustrated in FIG. 12, the second pressurizing surface 400 pressurizes the second pressurized surface 388 until the second moving member 390 returns to the steady-state position. Then, the first biasing member 310 rotates in the first rotation direction 902, and the positioning members 360 move in the direction away from the ideal axis L. As illustrated in FIG. 11, the positioning members 360 move to the first position illustrated in FIG. 6 when the second moving member 390 is located at the steady-state position.

Next, a behavior of each component in a case in which the second moving member 390 rotates in the first rotation direction 902 from the displaced position illustrated in FIG. 13 will be described. When the second moving member 390 is located at the position illustrated in FIG. 13, the second pressurizing surface 400 and the second pressurized surface 388 do not abut each other. Therefore, in a case in which the second moving member 390 rotates in the first rotation direction 902, the first moving member 380 and the positioning member 369 do not move until the second pressurizing surface 400 abuts the second pressurized surface 388. However, once the second pressurizing surface 400 abuts the second pressurized surface 388, the first moving member 380 and the positioning member 360 start to move. In this manner, the positioning members 360 move in the direction away from the ideal axis L. In other words, in a case in which the second moving member 390 rotates in the first rotation direction 902 from the displaced position illustrated in FIG. 13, the first moving member 380 do not rotate while the second moving member 390 rotate first until the second pressurized surface 388 and the second pressurizing surface 400 abut each other. After the second pressurized surface 388 and the second pressurizing surface 400 abut each other, the first moving member 380 and the second moving member 390 rotate together in the first rotation direction 902 with the abutting therebetween kept as it is. When the second moving member 390 is located at the steady-state position as illustrated in FIG. 11, the positioning members 360 move to the first position illustrated in FIG. 6 similarly to the case in which the second moving member 390 rotates in the first rotation direction 902 from the displaced position illustrated in FIG. 12.

In this manner, the second moving member 390 can cause the first moving member 380 to rotate about the ideal axis L when the second moving member 390 rotates about the ideal axis L. In other words, the second moving member 390 has a function of causing the first moving member 380 to rotate about the ideal axis L.

Also, referring to FIG. 11, the first member 300 includes a plurality of second biasing members 312 in one example. The second biasing members 312 are members with elasticity and are springs in one example. The second biasing members 312 are located between the second support base 330 and the second moving member 390 and bias the second moving member 390 in a tangential direction of the virtual circle VC in one example. In other words, the second biasing members 312 has a function of causing the second moving member 390 to rotate in the first rotation direction 902. Also, the second moving member 390 has a function of causing the first moving member 380 to rotate about the ideal axis L as described above. Therefore, if the second moving member 390 rotates in the first rotation direction 902, then the first moving member 380 also rotates in the first rotation direction 902 that is the same rotation direction. In other words, if the second biasing members 312 bias the second moving member 390, then the first moving member 380 rotates in the first rotation direction 902 along with the second moving member 390. In other words, the second biasing members 312 has also a function of causing not only the second moving member 390 but also the first moving member 380 to rotate.

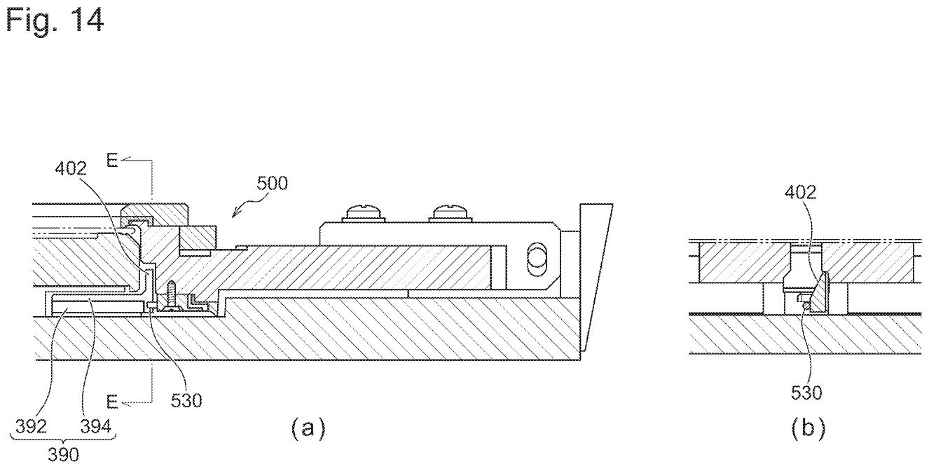

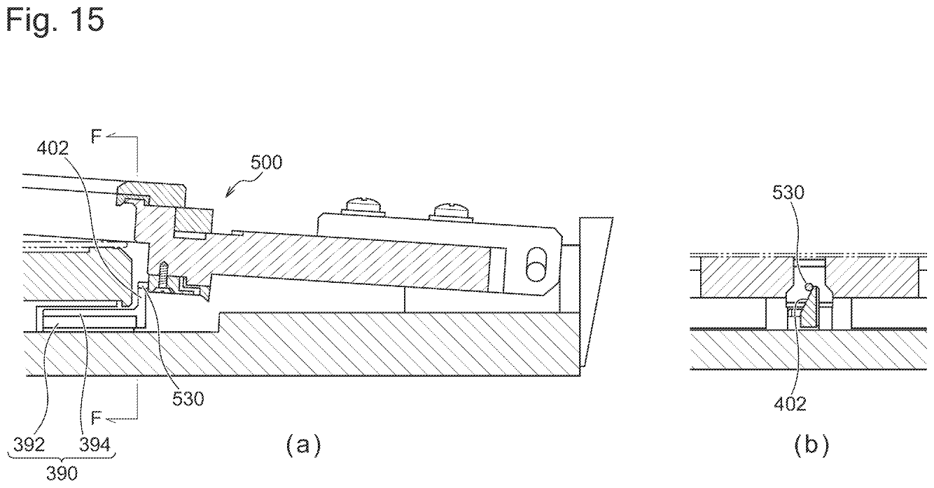

FIG. 14(a) is a schematic view of the section along D-D in FIG. 3, and FIG. 14(b) is a sectional view along E-E in FIG. 14(a). FIG. 15(a) is a schematic view of the section along D-D in FIG. 3 in a state in the process of closing of the second member 500, and FIG. 15(b) is a sectional view along F-F in FIG. 15(a). Referring to FIG. 14(a), the second member 500 includes an abutting member 530. The abutting member 530 is a protrusion 530 with a columnar shape fixed to the second member 500 in one example. The protrusion 530 has a columnar side peripheral surface configured to be able to abut an inclined surface 402. Also, the abutted member 394 of the first member 300 includes the inclined surface 402 inclined relative to a plane that perpendicularly intersects the ideal axis L (see FIG. 14(b)). The direction of the normal line of the inclined surface 402 includes a component in the direction of the ideal axis L and a component in the tangential direction of the virtual circle VC.

When the first member 300 and the second member 500 pinch the substrate W, the second member 500 moves from the position illustrated in FIG. 15 to the position illustrated in FIG. 14. At this time, the protrusion 530 can abut the inclined surface 402 and pressurize the inclined surface 402 in the direction in which the ideal axis L extends. Then, the second moving member 390 rotates in the second rotation direction 904 with a force that the inclined surface 402 receives from the protrusion 530. In other words, the second moving member 390 rotates from the steady-state position to the displaced position.

On the other hand, in a case in which the second member 500 is opened, the protrusion 530 that has pressurized the inclined surface 402 moves in the direction away from the inclined surface 402, that is, the direction in which the ideal axis L substantially extends. In this manner, the inclined surface 402 returns to the position before the protrusion 530 abuts the inclined surface 402 with the biasing force that the second moving member 390 receives from the second biasing members 312. In other words, the second moving member 390 gradually moves in the first rotation direction 902 and returns from the displaced position to the steady-state position by the second member 500 being opened (see FIG. 11).

Also, the substrate holder 200 is configured such that the rotation of the second moving member 390 achieved by the protrusion 530 and further the movement of the positioning members 360 in the direction of the ideal axis L when the first member 300 and the second member 500 pinch the substrate W are performed prior to the contact between the substrate sealing member 518 and the substrate W (see FIG. 4).

<Method for Pinching Substrate Positioned in Substrate Holder>

Next, a method for pinching the substrate W positioned in the substrate holder 200 from a state in which the substrate W is not placed on the support surface 342 (initial state) will be described.

First, the substrate W is placed on the support surface 342 in a state in which the second member 500 is opened as illustrated in FIG. 2. Then, the second member 500 is closed. At this time, the protrusion 530 of the second member 500 abuts the inclined surface 402 of the first member 300 and causes the second moving member 390 to rotate (see FIGS. 14 and 15). Once the second moving member 390 starts to rotate, then the first moving member 380 rotates along with the second moving member 390 as described above (see FIG. 9). Then, the positioning members 360 move in the direction of the ideal axis L by the first moving member 380 rotating. In this manner, the contact surfaces 376 of the positioning members 360 come into contact with the side end portions of the substrate W placed on the support surface 342 and push the substrate W in the direction of the ideal axis L. and the six positioning members 360 position the substrate W by pinching the substrate W from the surroundings. However, the second member 500 has not yet been completely closed when the positioning of the substrate W is completed. Therefore, the second member 500 is further closed. In this manner, the second moving member 390 further rotates in the first direction and moves up to the displaced position illustrated in FIG. 13. Note that the positioning members 360 cannot cause the substrate W to move anymore and the first moving member 380 cannot rotate at this time. Therefore, the first biasing members 310 are compressed.

Also, the substrate sealing member 518 comes into contact with the surface of the substrate W and seals the clearance between the substrate W and the second member 500 immediately before the second member 500 is completely closed. Thereafter, if the second member 500 is completely closed, then the pressure ring 506 is turned, and the second member 500 is fixed to the first member 300 with the clampers 302. The pinching of the substrate W positioned in the substrate holder 200 is completed hitherto.

<Effects of Substrate Holder>

Next, effects of the substrate holder 200 according to the first embodiment will be described below.

(First Effect)

A first effect is an effect achieved by the substrate holder 200 including the base 340, the six positioning members 360, the first moving member 380, and the first biasing members 310. As described above, the six positioning members 360 are biased in the direction in which the contact surfaces 376 approach the ideal axis L. Therefore, in a case in which the substrate W is placed on the support surface 342, the positioning members 360 move in the direction from the first position toward the second position. Then, the six positioning members 360 position the substrate W by pinching the substrate W placed on the support surface 342 of the base 340 from the surroundings. At this time, the first moving member 380 maintains a state in which the distances between the ideal axis L and the contact surfaces 376 of the positioning members 360 are equal to each other. Therefore, the six positioning members 360 can cause the center of the substrate W to be located on the ideal axis L at the time of the positioning. As a result, the center of the substrate W after the positioning is located on the ideal axis L even in a case in which the substrate W receives a frictional force and the like from the support surface 342. In other words, the substrate holder 200 can position the substrate W even in a case in which the substrate W receives a frictional force and the like from the support surface 342.

(Second Effect)

Also, if the second moving member 390 moves to the displaced position in a case in which the substrate holder 200 does not include the first biasing members 310, the positioning members 360 are closed up to a specific position. It is thus possible to position only the substrate W with an intended size. In a case in which the substrate holder 200 that does not include the first biasing members 310 positions the substrate W that is larger than an intended size, for example, the positioning members 360 move up to the specific position even after the positioning members 360 come into contact with the side end portions of the substrate W. In this case, there is a concern that the positioning members 360 apply an unnecessary load to the substrate W. Moreover, there is a concern that the substrate W is broken due to the load.

However, the substrate holder 200 includes the first biasing members 310. Also, the positioning members 36) are biased in the direction in which the contact surfaces 376 approach the ideal axis L with the biasing force delivered from the first biasing members 310. Therefore, the positioning members 360 do not push the substrate W with a force that is greater than the biasing force delivered from the first biasing members 310. In other words, an unnecessary load that is greater than the biasing force of the first biasing members 310 is not applied to the substrate W, and the substrate holder 200 can curb breakage of the substrate W even in a case in which the substrate W has a dimensional tolerance.

(Third Effect)

Also, in a case in which the substrate holder 200 that does not include the first biasing members 310 positions the substrate W that is smaller than an intended size, a space is generated between the substrate W and the positioning members 360 when the positioning members 360 are located at specific positions. Then, the substrate W can freely move in accordance with the space, and there is a concern that the substrate W is not accurately be positioned.

However, the substrate holder 200 includes the first biasing members 310. Also, the positioning members 360 are configured to be movable from the first position at which the distances between the ideal axis L and the contact surfaces 376 are longer than the radius of the substrate W to the second position at which the distances between the ideal axis L and the contact surfaces 376 are shorter than the radius of the substrate W when the substrate W is not placed on the base 340. Therefore, even in a case in which the size of the substrate W changes within a range of a dimensional tolerance, and the substrate W is smaller than the intended size, the six positioning members 360 can position the substrate W by pinching the substrate W from the surroundings.

(Fourth Effect)

Also, the first moving member 380 and the second moving member 390 rotate in the second rotation direction 904, and the positioning members 360 move in the direction toward the ideal axis L and position the substrate W in the substrate holder 200 by the second member 500 being closed as described above. In other words, the substrate holder 200 can position the substrate W only by the second member 500 being closed.

(Fifth Effect)

A fifth effect is an effect achieved by the substrate holder 200 including the positioning members 360, the first moving member 380, the second moving member 390, and the first biasing members 310. As described above, in a case in which the second moving member 390 rotates in the second rotation direction 904, the first moving member 380 rotates (see FIG. 11). Also, the positioning members 360 are caused to move, and each positioning member 360 pinches the side end portion of the substrate W to perform positioning, by the first moving member 380 rotating. Additionally, if the positioning members 360 completes the positioning of the substrate W, the positioning members 360 cannot move due to a reactive force from the substrate W, and the first moving member 380 also cannot rotate. However, since the first biasing members 310 are located between the first pressurized surface 386 of the first moving member 380 and the first pressurizing surface 398 of the second moving member 390, the first biasing members 310 are compressed, and the second moving member 390 can thus rotate. In other words, the second moving member 390 can rotate in a state in which the positioning members 360 and the first moving member 380 are stopped in the substrate holder 200.

(Sixth Effect)

In general, there is a concern that in a case in which the substrate sealing member 518 comes into contact with the substrate W to seal the portion between the first member 300 and the substrate W, the substrate W moves above the support surface 342 due to a pressure from the substrate sealing member 518. In this case, there is a concern that the substrate holder 200 cannot hold the substrate W in a state in which the substrate holder 200 is appropriately positioned even if the substrate W is appropriately positioned.

However, rotation of the second moving member 390 when the first member 300 and the second member 500 pinch the substrate W is performed prior to contact between the substrate sealing member 518 and the substrate W in the substrate holder 200. In other words, the second moving member 390 rotates, the six positioning members 360 position the substrate W by pinching the substrate W, and the substrate sealing member 518 then come into contact with the substrate W. Therefore, since the six positioning members 360 pinch the substrate W when the substrate W receives a pressure from the substrate sealing member 518, the substrate W is less likely to move above the support surface 342. In other words, the substrate holder 200 can curb deviation of the substrate W due to the pressure from the substrate sealing member 518.

<Modification Examples of Substrate Holder>

### First Modification Example

In the first embodiment, the first member 300 includes the positioning members 360, the first biasing members 310, the first moving member 380, and the second moving member 390. However, the second member 500 instead of the first member 300 may include the positioning members 360, the first biasing members 310, the first moving member 380, and the second moving member 390. This is because the substrate holder 200 can position the substrate W in such a case as well. Note that a member including the positioning members 360, the first biasing members 310, and the first moving member 380 can be referred to as a first holding member, and the other member can be referred to as a second holding member from among the first member 300 and the second member 500.

### Second Modification Example

Also, the positioning members 360 include the pins 370 as the engaged portions 370, and the first moving member 380 includes the long holes 384 as the engaging portions 384 in the first embodiment. However, the engaged portions 370 may not be the pins 370, and the engaging portions 384 may not be the long holes 384. The engaged portions 370 and the engaging portions 384 may be any members that can cause the positioning members 360 to move in the radial direction of the virtual circle VC when the first moving member 380 rotates. For example, the engaged portions 370 may be long holes, and the engaging portions 384 may be pins. The positioning members 360 can move in the radial direction of the virtual circle VC by the first moving member 380 being rotated even in such a case as well.

### Third Modification Example

Also, the second biasing members 312 bias the second moving member 390 in the tangential direction of the virtual circle VC in the first embodiment. However, it is only necessary for the second biasing members 312 to be able to bias the second moving member 390 in a direction intersecting the radial direction of the virtual circle VC. The second biasing members 312 can cause the second moving member 390 to rotate in the first rotation direction 902 with the biasing force thereof in such a case as well.

### Fourth Modification Example

Also, the abutting member 530 is the protrusion 530, and the abutted member 394 includes the inclined surface 402 in the first embodiment. However, the abutting member 530 may not be the protrusion 530, and the abutted member 394 may not include the inclined surface 402. In regard to the abutting member 530 and the abutted member 394, it is only necessary for the abutting member 530 to be a member that can cause the second moving member 390 to rotate by the abutting member 530 pressurizing the abutted member 394 when the first member 300 and the second member 500 pinch the substrate W. For example, the abutting member 530 includes an inclined surface, and the abutted member 394 may be a protrusion. The abutting member 530 can cause the second moving member 390 to rotate by the abutting member 530 pressurizing the abutted member 394 when the first member 300 and the second member 500 pinch the substrate W in such a case as well.

### Fifth Modification Example

Also, the first member 300 includes the six positioning members 360 in the first embodiment. However, the first member 300 may not include the six positioning members 360, and it is only necessary for the first member 300 to include three or more positioning members 360. If the first member 300 includes three or more positioning members 360, the positioning members 360 can position the substrate W by pinching the substrate W from the surroundings.

### Sixth Modification Example

Also, the substrate holder 200 is not limited to the plating apparatus 100 and may be used in a substrate treatment apparatus other than the plating apparatus 100, such as an etching apparatus or a washing apparatus. Note that the plating apparatus 100 is included in the substrate treatment apparatus.

### Seventh Modification Example

In the aforementioned embodiment, the second moving member 390 rotates in the direction corresponding to the second rotation direction 904 by being pressurized by the abutting member 530 and biases the first moving member 380 in the second rotation direction 904 via the first biasing members 310. The substrate holder 200 according to the seventh modification example does not include the second moving member 390, the abutting member 530, the abutted member 394, and the second biasing members 312. The first biasing members 310 are provided between the first moving member 380 and a structural wall of the first member 300 and bias the first moving member 380 in the second rotation direction 904. The first moving member 380 includes a pressurized portion that is biased in the direction corresponding to the first rotation direction 902 by a pressurizing member that is different from the abutting member 530 of the second member 500 or a different structure other than the substrate holder 200. The positioning member 360 is constantly biased in the direction toward the ideal axis L by the first biasing member 310. The first moving member 380 is rotated in the first rotation direction 902 by the pressurized portion being biased in the first rotation direction 902. In this manner, it is possible to cause the positioning member 360 to move in the direction away from the ideal axis L when the substrate W is received on the support surface 342 of the first member 300. Then, the substrate holder 200 according to the seventh modification example can position the substrate W by the biasing of the pressurized portion in the first rotation direction 902 being released after the substrate W is placed on the support surface 342.

### Eighth Modification Example

In the aforementioned embodiment, the first biasing members 310 are provided in order to prevent the substrate W from being broken when the positioning members 360 position the substrate W and address variations in size of the substrate W. The substrate holder 200 according to an eighth modification example does not include the first biasing members 310. In other words, the form in which the first biasing members 310 are not included means that the first moving member 380 and the second moving member 390 are integrally formed if explanation is given in accordance with the aforementioned embodiment. The positioning members 360 move to positions at a specific distance from the ideal axis L if the second member 500 is closed. The contact surfaces 376 of the positioning members 360 may be provided with elastic members to prevent breakage of the substrate W. Since each positioning member 360 moves in the direction toward the ideal axis L and positions the substrate W with the contact surface 376 of each positioning member 360 maintaining the distance to the ideal axis L in the substrate holder 200 according to the eighth modification example as well, it is possible to perform accurate positioning. In the case in which the contact surfaces 376 of the positioning members 360 are provided with the elastic members, hardness or elastic moduli of the elastic members are determined such that it is possible to prevent breakage of the substrate W and to accurately position the substrate W.

### Ninth Modification Example

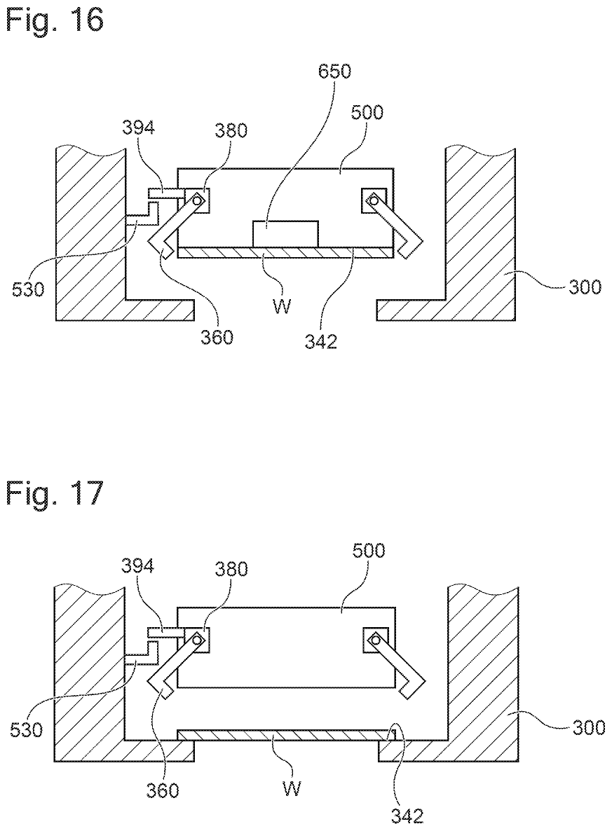

The substrate holder 200 is a substrate holder in which the substrate W is to be disposed in a vertical position relative to the plating tank and that is to be immersed into the plating solution. However, the substrate holder 200 is not limited to such an embodiment. For example, the substrate holder 200 may be a substrate holder (cup-type substrate holder) in which the substrate W is to be disposed in a horizontal position in the plating tank as illustrated in FIG. 16. Note that FIG. 16 is a schematic view illustrating a modification example of the substrate holder 200.

In this case, the first member 300 may include the abutting member 530, and the second member 500 may include the positioning members 360, the first moving member 380, the abutted member 394, a Bernoulli chuck 650, and a support surface 342 as illustrated in FIG. 16.

In the substrate holder 200 according to the ninth modification example, the substrate W is suctioned by the Bernoulli chuck 650, and the second member 500 holds the substrate W. Also, the first member 300 and the support surface 342 of the second member 500 pinch the substrate W by the second member 500 being lowered. The substrate W is positioned by the abutting member 530 included in the first member 300 abutting the abutted member 394 and by the positioning members 360 moving when the second member 500 is lowered. Therefore, the substrate holder 200 can position the substrate W even if the substrate holder 200 is a cup-type substrate holder in this manner.

### Tenth Modification Example

Also, when the substrate holder 200 is a cup-type substrate holder, the first member 300 may include the abutting member 530 and the support surface 342, and the second member 500 may include the positioning member 360, the first moving member 380, and the abutted member 394 as illustrated in FIG. 17. Here, FIG. 17 is a schematic view illustrating another modification example of the substrate holder 200.

In the substrate holder 200 according to a tenth modification example, the substrate W is placed on the support surface 342. Then, the first member 300 and the second member 500 pinch the substrate W by the second member 500 being lowered. Also, the substrate W is positioned by the abutting member 530 included in the first member 300 abutting the abutted member 394 and by the positioning members 360 moving when the second member 500 is lowered.

### Eleventh Modification Example

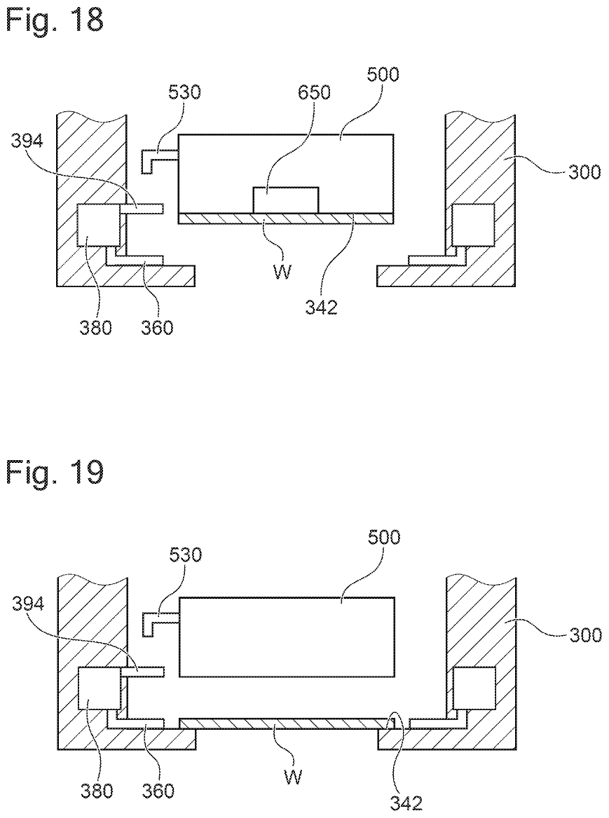

Also, when the substrate holder 200 is a cup-type substrate holder, the first member 300 may include the positioning members 360, the first moving member 380, and the abutted member 394, and the second member 500 may include the abutting member 530, the Bemoulli chuck 650, and the support surface 342 as illustrated in FIG. 18. Here, FIG. 18 is a schematic view illustrating another modification example of the substrate holder 200.

In the substrate holder 200 according to an eleventh modification example, the substrate W is suctioned by the Bernoulli chuck 650, and the second member 500 holds the substrate W. Then, the first member 300 and the support surface 342 of the second member 500 pinch the substrate W by the second member 500 being lowered. Also, the substrate W is positioned by the abutting member 530 included in the second member 500 abutting the abutted member 394 and by the positioning members 360 moving when the second member 500 is lowered.

### Twelfth Modification Example

Also, when the substrate holder 200 is a cup-type substrate holder, the first member 300 may include the positioning member 360, the first moving member 380, the abutted member 394, and the support surface 342, and the second member 500 may include the abutting member 530 as illustrated in FIG. 19. Here, FIG. 19 is a schematic view illustrating another modification example of the substrate holder 200.

In the substrate holder 200 according to a twelfth modification example, the substrate W is placed on the support surface 342. Then, the first member 300 and the second member 500 pinch the substrate W by the second member 500 being lowered. Also, the substrate W is positioned by the abutting member 530 included in the second member 500 abutting the abutted member 394 and by the positioning members 360 moving when the second member 500 is lowered.

[Supplement]

Although a part or entirety of the aforementioned embodiment can also be described as in the following supplement, the embodiment is not limited to the following supplement.

(Supplement 1)

A substrate holder according to Supplement 1 is a substrate holder that includes a support surface for supporting a substrate and positions the substrate such that a center axis of the substrate is located on an ideal axis extending in a direction perpendicularly intersecting the support surface, the substrate holder including: a first holding member; a second holding member adapted to pinch the substrate with the first holding member; three or more positioning members including contact surfaces that come into contact with side end portions of the substrate; a first moving member including a plurality of engaging portions that are engaged with the positioning members such that the positioning members are moved at the same time with a state in which distances between the ideal axis and the contact surfaces of the positioning members are equal to each other maintained; and a first biasing member adapted to bias the first moving member, in which the first moving member delivers a biasing force of the first biasing member to each of the positioning members via the engaging portions, and each of the positioning members is biased in a direction in which the contact surfaces approach the ideal axis with the biasing force delivered from the first biasing member.

In the substrate holder according to Supplement 1, each positioning member is biased in the direction in which the contact surface approaches the ideal axis. Therefore, in a case in which the substrate is placed on the support surface, the contact surfaces of the positioning members come into contact with the side end portions of the substrate and push the substrate in the direction of the ideal axis. In this manner, the three or more positioning members position the substrate by pinching the substrate from the surroundings. At this time, the first moving member maintains the state in which the distances between the ideal axis and the contact surfaces of the positioning members are equal to each other. Therefore, if the substrate has a circular shape, then the three or more positioning members can cause the center of the pinched substrate to be located on the ideal axis. As a result, the center of the substrate after the positioning is located on the ideal axis even in a case in which the substrate receives a frictional force and the like from the support surface. In other words, the substrate holder can position the substrate even in a case in which the substrate receives a frictional force and the like from the support surface.

Also, each positioning member is biased in the direction in which the contact surface approaches the ideal axis with the biasing force delivered from the first biasing member. Therefore, the positioning members do not push the substrate with a force that is greater than the biasing force delivered from the first biasing member. In other words, an unnecessary load that is greater than the biasing force of the first biasing member is not applied to the substrate, and the substrate holder can curb breakage of the substrate even in a case in which the substrate has a dimensional tolerance.

(Supplement 2)

According to the substrate holder in Supplement 2, the positioning members include engaged portions with which the engaging portions are movably engaged, the first moving member is configured to be rotatable about the ideal axis, and when the first moving member rotates about the ideal axis, rotation of the first moving member is delivered to the positioning members via the engaging portions and engaged portions, and the positioning members move in a radial direction of a virtual circle around the ideal axis, in the substrate holder described in Supplement 1.

The substrate holder according to Supplement 2 can deliver the biasing force of the first biasing member to the positioning members via the engaging portions and the engaged portions by the first moving member rotating about the ideal axis. Also, the substrate holder can cause the positioning members to move in the radial direction of the virtual circle around the ideal axis with the biasing force of the first biasing member.

(Supplement 3)

According to the substrate holder in Supplement 3, the engaged portions are first pins or first long holes, and the engaging portions are second long holes to establish engagement with the first pins or second pins to establish engagement with the first long holes, in the substrate holder described in Supplement 2.

According to the substrate holder in Supplement 3, the second long holes or the second pins of the first moving member can establish engaged with the first pins or the first long holes of the positioning members.

(Supplement 4)

According to the substrate holder in Supplement 4, the first pins and the second pins extend in parallel with the ideal axis, and a longitudinal direction of the first long holes and a longitudinal direction of the second long holes are directions that intersect the radial direction and a circumferential direction of the virtual circle, in the substrate holder described in Supplement 3.

According to the substrate holder in Supplement 4, the second long holes or the second pins included in the first moving member move, and the first pins and the first long holes engaged with the second long holes or the second pins are pulled in the direction of the ideal axis, by the first moving member being rotated. In this manner, the positioning members including the second long holes or the second pins move in the radial direction of the virtual circle. In other words, the substrate holder can cause the positioning members to move in the radial direction of the virtual circle using the first pins or the first long holes and the second long holes or the second pins.

(Supplement 5)

The substrate holder in Supplement 5 further includes: a second moving member adapted to cause the first moving member to rotate about the ideal axis, in the substrate holder according to any one of Supplements 2 to 4.

According to the substrate holder in Supplement 5, the second moving member can cause the first moving member to rotate about the ideal axis.

(Supplement 6)

According to the substrate holder in Supplement 6, the second moving member includes a first pressurizing surface and is configured to be rotatable about the ideal axis, the first moving member includes a first pressurized surface, and the first biasing member is located between the first pressurized surface of the first moving member and the first pressurizing surface of the second moving member and biases the first moving member via the first pressurized surface, in the substrate holder described in Supplement 5.

According to the substrate holder in Supplement 6, the first biasing member can bias the first moving member via the first pressurized surface.

(Supplement 7)

According to the substrate holder in Supplement 7, the second moving member includes a second pressurizing surface and is configured to be rotatable about the ideal axis, the first moving member includes a second pressurized surface facing the second pressurizing surface, the first moving member is biased in a direction in which the second pressurized surface approaches the second pressurizing surface, and the second pressurized surface abuts the second pressurizing surface, by the first biasing member biasing the first moving member, and when the second moving member rotates about the ideal axis, the second pressurized surface rotates along with the second pressurizing surface, and the first moving member rotates in the same rotation direction as a rotation direction of the second moving member, in the substrate holder described in Supplement 5 or 6.

According to the substrate holder in Supplement 7, the first moving member rotates in the same rotation direction as the rotation direction of the second moving member if the second moving member rotates. Also, the positioning members are caused to move by the first moving member being rotated, and each positioning member pinches the side end portion of the substrate to perform positioning. Also, once the positioning members complete the positioning of the substrate, the positioning members cannot move, and the moving member cannot rotate, due to a reactive force from the substrate. However, since the first biasing member is located between the first pressurized surface of the first moving member and the first pressurizing surface of the second moving member, the second moving member can rotate by the first biasing member being compressed. In other words, according to the substrate holder, the second moving member can rotate in a state in which the positioning members and the first moving member are stopped.

(Supplement 8)

The substrate holder according to Supplement 8 further includes: a second biasing member adapted to cause the first moving member to rotate in a first rotation direction around the ideal axis, in which when the first moving member rotates in the first rotation direction, the contact surfaces move in a direction away from the ideal axis in conjunction with rotation of the first moving member, in the substrate holder according to any one of Supplements 1 to 7.

According to the substrate holder in Supplement 8, the second biasing member can cause the first moving member to rotate in the first rotation direction. Also, the substrate holder can cause the contact surfaces to move in the direction away from the ideal axis in conjunction with the rotation of the first moving member.

(Supplement 9)

According to the substrate holder in Supplement 9, the second biasing member biases the second moving member in a direction that intersects a radial direction of a virtual circle around the ideal axis and causes the second moving member to rotate in the first rotation direction, in the substrate holder described in Supplement 8 depending from Supplement 7.

According to the substrate holder in Supplement 9, the second biasing member can cause the second moving member to rotate in the first rotation direction by the second biasing member biasing the second moving member in the direction that intersects the radial direction of the virtual circle around the ideal axis.

(Supplement 10)

According to the supplement holder in Supplement 10, the positioning members, the first biasing member, and the second moving member are provided in the first holding member, the second holding member includes an abutting member, the second moving member includes an abutted member that is to abut the abutting member of the second holding member, and when the first holding member and the second holding member pinch the substrate, the abutting member of the second holding member causes the second moving member to rotate about the ideal axis by the abutting member abutting the abutted member of the second moving member and by the abutting member pressurizing the abutted member, in the substrate holder according to Supplement 5 or any one of Supplement 6 to 9 depending from Supplement 5.

According to the substrate holder in Supplement 10, the abutting member can cause the second moving member to rotate about the ideal axis when the first holding member and the second holding member pinch the substrate.

(Supplement 11)

According to the substrate holder in Supplement 11, the abutting member is a protrusion fixed to the second holding member, the abutted member includes an inclined surface that is inclined relative to a plane perpendicularly intersecting the ideal axis, when the first holding member and the second holding member pinch the substrate, the protrusion abuts the inclined surface and pressurizes the inclined surface in a direction in which the ideal axis extends, and the second moving member is configured to rotate in a second rotation direction that is a rotation direction opposite to the first direction with a force that the inclined surface receives from the protrusion, in the substrate holder described in Supplement 10.

According to the substrate holder in Supplement 11, the protrusion can cause the second moving member to rotate in the second rotation direction by the protrusion abutting the inclined surface and pressurizing the inclined surface when the first holding member and the second holding member pinch the substrate. Also, the first moving member also rotates in the second rotation direction, by the second moving member rotating in the second rotation direction, and the positioning members move the direction toward the ideal axis, thereby positioning the substrate. In other words, the substrate holder can position the substrate merely by the second holding member closing.

(Supplement 12)

According to the substrate holder in Supplement 12, the second holding member includes a substrate sealing member adapted to establish sealing between the second holding member and the substrate, and rotation of the second moving member caused by the abutting member when the first holding member and the second holding member pinch the substrate is performed prior to contact between the substrate sealing member and the substrate, in the substrate holder according to Supplement 10 or 11.

In general, there is a concern that the substrate moves above the support surface due to a pressure from the substrate sealing member in a case in which the substrate seaming member comes into contact with the substrate to establish sealing between the first holding member and the substrate. In this case, there is a concern that the substrate holder cannot hold the substrate in an appropriately positioned state even if the positioning of the substrate is appropriately performed.

However, according to the substrate holder in Supplement 12, the rotation of the second moving member when the first holding member and the second holding member pinch the substrate is performed prior to the contact between the substrate sealing member and the substrate. In other words, the substrate sealing member comes into contact with the substrate after the second moving member rotates and the three or more positioning members position the substrate by pinching the substrate. Therefore, since the three or more positioning members pinch the substrate when the substrate receives the pressure from the substrate sealing member, the substrate is less likely to move above the support surface. In other words, the substrate holder can curb deviation of the substrate due to the pressure from the substrate sealing member.

(Supplement 13)

According to the substrate holder in Supplement 13, the first moving member is an arc-shaped member including a pair of side surfaces extending in a circumferential direction of a virtual circle around the ideal axis, and the substrate holder further includes a guide member adapted to come into contact with each of the side surfaces and guide the first moving member in the circumferential direction of the virtual circle around the ideal axis, in the substrate holder according to any one of Supplements 1 to 12.

According to the substrate holder in Supplement 13, the first moving member can rotate about the ideal axis since the first moving member is guided by the guide member.

(Supplement 14)

According to the substrate holder in Supplement 14, the positioning members are configured to be movable from a first position at which the distances between the ideal axis and the contact surfaces are longer than a radius of the substrate to a second position at which the distances between the ideal axis and the contact surfaces are shorter than the radius of the substrate, in any one of Supplements 1 to 13.

In a case in which the substrate holder that does not include the first biasing member positions the substrate that is smaller than an intended size, a space is generated between the substrate and the positioning members when the positioning members are located at specific positions. Also, the substrate can freely move by the amount corresponding to the space, and there is a concern that the substrate is not accurately positioned.

However, the substrate holder according to the form 14 includes the first biasing member. Also, the positioning members are configured to be movable from the first position at which the distances between the ideal axis and the contact surfaces are longer than the radius of the substrate to the second position at which the distances between the ideal axis and the contact surfaces are shorter than the radius of the substrate. Therefore, even in the case in which the substrate is smaller than the intended size, the three or more positioning members can position the substrate by pinching the substrate from the surroundings.

(Supplement 15)

A substrate treatment apparatus according to Supplement 15 is adapted to perform a plating treatment on a substrate using the substrate holder according to any one of Supplements 1 to 14.

The substrate treatment apparatus according to Supplement 15 can perform a treatment using the substrate holder capable of positioning the substrate and capable of curbing breakage of the substrate even in a case in which the substrate has a dimensional tolerance.

Although only some embodiments of the present invention have been described above, those skilled in the art will be able to easily understand that various modifications or improvements can be added to the illustrated embodiments without substantially departing from the novel teachings and advantages of the present invention. Therefore, embodiments achieved by adding such various modifications or improvements are also intended to be included within the technical scope of the present invention. Also, the aforementioned embodiments may be arbitrarily combined.

### REFERENCE SIGNS LIST

100: Plating apparatus
200: Substrate holder
300: First member
310: First biasing member
312: Second biasing member
314: Guide member
320: First support base
330: Second support base
336: Guide member
340: Base
342: Support surface
360: Positioning member
370: Pin
376: Contact surface
380: First moving member
384: Long hole
386: First pressurized surface
388: Second pressurized surface
390: Second moving member
394: Abutted member
398: First pressurizing surface
400: Second pressurizing surface
402: inclined surface
500: Second member
518: Substrate sealing member
520: Holder sealing member
530: Abutting member
902: First rotation direction
904: Second rotation direction
L: Center axis, ideal axis
W: Substrate

1. A substrate holder that includes a support surface for supporting a substrate and positions the substrate such that a center axis of the substrate is located on an ideal axis extending in a direction perpendicularly intersecting the support surface, the substrate holder comprising:
a first holding member;
a second holding member adapted to pinch the substrate with the first holding member;
three or more positioning members including contact surfaces that come into contact with side end portions of the substrate;
a first moving member including a plurality of engaging portions that are engaged with the positioning members such that the positioning members are moved at the same time with a state in which distances between the ideal axis and the contact surfaces of the positioning members are equal to each other maintained; and
a first biasing member adapted to bias the first moving member,
wherein the first moving member delivers a biasing force of the first biasing member to each of the positioning members via the engaging portions, and
each of the positioning members is biased in a direction in which the contact surfaces approach the ideal axis with the biasing force delivered from the first biasing member.

2. The substrate holder according to claim 1,
wherein the positioning members include engaged portions with which the engaging portions are movably engaged,
the first moving member is configured to be rotatable about the ideal axis, and
when the first moving member rotates about the ideal axis, rotation of the first moving member is delivered to the positioning members via the engaging portions and engaged portions, and the positioning members move in a radial direction of a virtual circle around the ideal axis.

3. The substrate holder according to claim 2,
wherein the engaged portions are first pins or first long holes, and
the engaging portions are second long holes to establish engagement with the first pins or second pins to establish engagement with the first long holes.

4. The substrate holder according to claim 3,
wherein the first pins and the second pins extend in parallel with the ideal axis, and
a longitudinal direction of the first long holes and a longitudinal direction of the second long holes are directions that intersect the radial direction and a circumferential direction of the virtual circle.

5. The substrate holder according to claim 2, further comprising:
a second moving member adapted to cause the first moving member to rotate about the ideal axis.

6. The substrate holder according to claim 5,
wherein the second moving member includes a first pressurizing surface and is configured to be rotatable about the ideal axis,
the first moving member includes a first pressurized surface, and
the first biasing member is located between the first pressurized surface of the first moving member and the first pressurizing surface of the second moving member and biases the first moving member via the first pressurized surface.

7. The substrate holder according to claim 5,
wherein the second moving member includes a second pressurizing surface and is configured to be rotatable about the ideal axis,
the first moving member includes a second pressurized surface facing the second pressurizing surface,
the first moving member is biased in a direction in which the second pressurized surface approaches the second pressurizing surface, and the second pressurized surface abuts the second pressurizing surface, by the first biasing member biasing the first moving member, and
when the second moving member rotates about the ideal axis, the second pressurized surface rotates along with the second pressurizing surface, and the first moving member rotates in the same rotation direction as a rotation direction of the second moving member.

8. The substrate holder according to claim 1, further comprising:
a second biasing member adapted to cause the first moving member to rotate in a first rotation direction around the ideal axis,
wherein when the first moving member rotates in the first rotation direction, the contact surfaces move in a direction away from the ideal axis in conjunction with rotation of the first moving member.

9. The substrate holder according to claim 8, wherein the second biasing member biases the second moving member in a direction that intersects a radial direction of a virtual circle around the ideal axis and causes the second moving member to rotate in the first rotation direction.

10. The substrate holder according to claim 5,
wherein the positioning members, the first biasing member, and the second moving member are provided in the first holding member,
the second holding member includes an abutting member,
the second moving member includes an abutted member that is to abut the abutting member of the second holding member, and
when the first holding member and the second holding member pinch the substrate, the abutting member of the second holding member causes the second moving member to rotate about the ideal axis by the abutting member abutting the abutted member of the second moving member and by the abutting member pressurizing the abutted member.

11. The substrate holder according to claim 10,
wherein the abutting member is a protrusion fixed to the second holding member,
the abutted member includes an inclined surface that is inclined relative to a plane perpendicularly intersecting the ideal axis,
when the first holding member and the second holding member pinch the substrate, the protrusion abuts the inclined surface and pressurizes the inclined surface in a direction in which the ideal axis extends, and
the second moving member is configured to rotate in a second rotation direction that is a rotation direction opposite to the first rotation direction with a force that the inclined surface receives from the protrusion.

12. The substrate holder according to claim 10,
wherein the second holding member includes a substrate sealing member adapted to establish sealing between the second holding member and the substrate, and
rotation of the second moving member caused by the abutting member when the first holding member and the second holding member pinch the substrate is performed prior to contact between the substrate sealing member and the substrate.

13. The substrate holder according to claim 1,
wherein the first moving member is an arc-shaped member including a pair of side surfaces extending in a circumferential direction of a virtual circle around the ideal axis, and
the substrate holder further includes a guide member adapted to come into contact with each of the side surfaces and guide the first moving member in the circumferential direction of the virtual circle around the ideal axis.

14. The substrate holder according to claim 1, wherein the positioning members are configured to be movable from a first position at which the distances between the ideal axis and the contact surfaces are longer than a radius of the substrate to a second position at which the distances between the ideal axis and the contact surfaces are shorter than the radius of the substrate.

15. A substrate treatment apparatus adapted to perform a plating treatment on a substrate using the substrate holder according to claim 1.
